(19) United States
(12) Patent Application Publication
(10) Pub. No.: US 2008/0018178 A1
(43) Pub. Date: Jan. 24, 2008

(54) Cabled control/transmission device with directional light projector

(76) Inventor: Tai-Her Yang, Si-Hu Town (TW)

Correspondence Address: BACON & THOMAS, 4th Floor, 625 Slaters Lane, Alexandria, VA, 22314-1176, US

(21) Appl. No.: 11/491,287

(22) Filed: Jul. 24, 2006

(51) Int. Cl. H05K 7/14

(52) U.S. Cl. 307/149

(57) ABSTRACT

A cabled control/transmission device with a directional light projector of the present invention features one control/transmission device taking conducting wire as the signal media, as its light projector can project visible light on a display, functioned as the auxiliary assistance of presentation, the lighting beam, or a selection between the output light spot indication and lighting beam by means of adjusting the focal length.

### BACKGROUND OF THE INVENTION

(a) Field of the Invention

The present invention is related to a cabled control/transmission device with a directional light projector, and more particularly, to one that projects on a display or marks on an object by means of a light projector to output light spot indication in visible light as auxiliary assistance of presentation, or functions as lighting beam, or serving for selection between light spot indication or lighting beam by adjusting focus. Present invention is applicable to various types of information systems, communication systems, amusement systems, monitor systems, computer, printer, recording device, TV, TV game, cable controlled toys, or any other electric home appliances, other electric devices having cables as control or transmission media for control or transmit message from the cabled control /transmission device with directional light projector.

(b) Description of the Prior Art

Whereas in a presentation with aid from conventional cabled control or transmission system operating with wire as media, it may become awkward by having to hold two objects including a laser pen as auxiliary projection to mark on the display or an object while controlling the primary projector.

### SUMMARY OF THE INVENTION

The present invention which relates to a cabled control/transmission device with a directional light projector features one control/transmission device taking conducting wire as the media, by setting its light projector can project visible light spot on a display, functioned as the auxiliary assistance of presentation, or project the lighting beam, or a selection between the output light spot indication and lighting beam by means of adjusting the focal length.

### BRIEF DESCRIPTION OF THE DRAWINGS

FIG. 1 is a circuit block chart of a cabled control/transmission device adapted with a directional light projector of the present invention.

### DETAILED DESCRIPTION OF THE PREFERRED EMBODIMENTS

The present invention relates to a cabled control/transmission device with a directional light projector which can project visible light on a display or an object, functioned as the auxiliary assistance of presentation, the lighting beam, or a selection between the output light spot indication and lighting beam by means of adjusting the focal length.

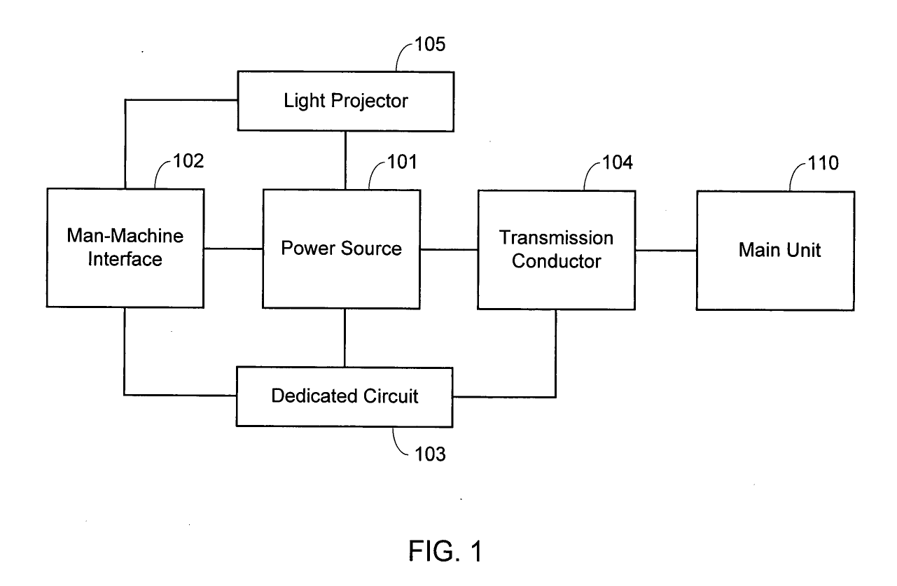

As illustrated in FIG. 1 for a circuit block chart of a cabled control/transmission device adapted with a directional light projector, the present invention is essentially comprised of:

a power source 101: supplies power from AC city power, or a main unit 110 to be described below adapted with the present invention for control and transmission, or a local DC source provide power to a man-machine operation interface 102, a dedicated circuit 103, and a light projector 105 to be described below;

the man-machine operation interface 102: an optional items provided according to the requirements of the applied installations, including switch, press button, keyboard, display, or one or multiple conventional operation interface in the form of video, audio, optical or RF to operate the dedicate circuit 103 and the light projector 105 that generates visible light;

the dedicated circuit 103: comprised of solid state electronic device, or dynamo-electric device, or integrated circuit and related software to provide functioning operation of the cabled control/transmission device adapted with a directional light projector;

a transmission cable 104: comprised of a electric or optical conducting cable that is directly connected to the main unit 110 or through a plug and socket set and may be provided as follows as applicable:

(1) An optical fiber to transmit optical signals and a conductor to transmit electric power are linked either directly or respectively by means of optical and electric linking devices connecting to the main unit 110 subject to be controlled or transmission by the optical fiber and the electric conductor; or (2) An optical fiber to transmit optical signals is provided and directly linked to or linked by means of an optical linking device to the main unit 110 subject to be controlled or transmission by the optical fiber while the light projector 105 operates on its local DC source; or (3) A transmission electric conducting cable for conduction is provided and directly linked to or linked by means of an electric linking device to the main unit 110 subject to be controlled or transmission by the conductor to transmit electric signals and power; and

the light projector 105: disposed to the casing of the control device and comprised of laser, diode, and associate drive circuit, or LED, bulb, or any other device to convert electric energy into visible light energy and associate drive circuit.

The cabled control/transmission device adapted with a directional projector of the present invention is provided to control or transmit signals to the main unit 110 including that applied in information systems, communication systems, games, monitor systems, AV devices, computer, printer, recording devices, power toys, cabled control toys or any other home electric appliances, or any other electric appliance operating with conducting cable as the control or transmission media for the cabled control/transmission device adapted with the directional light projector to control or transmit messages.

The cabled control/transmission device adapted with the directional light projector of the present invention can be applied in hand held control device, mouse, trackball, keyboard, handset, MP3 player or any other control or transmission system that operates on a conducting cable as transmission carrier.

The following applications and installation methods are available for selection for the light projector 105 in the cabled control/transmission device adapted with the light projector to produce visible light if applicable:

(1) Emitting visible light-spot indication for the visible light spot to serve auxiliary assistance of presentation;

(2) Emitting light projection beam for lighting purpose or for functioning as auxiliary assistance of presentation;

(3) An optional optical lens and mechanism with range adjustable may be provided as required for focus selection as the light spot or to diffuse for lighting purpose.

Accordingly, the cabled control/transmission device adapted with the directional light projector of the present invention while operating with the conducting cable as control or transmission media is characterized in that it is provided with the light projector 105 to serve as auxiliary assistance for presentation or auxiliary lighting to enhance operation convenience.

1. A cabled control/transmission device with a directional light projector features one control/transmission device taking conducting wire as the signal media, as its light projector can project visible light on a display, functioned as the auxiliary assistance of presentation, the lighting beam, or a selection between the output light spot indication and lighting beam by means of adjusting the focal length is essentially comprised of:
a power source 101: supplies power from AC city power, or a main unit 110 to be described below adapted with the present invention for control and transmission, or a local DC source provide power to a man-machine operation interface 102, a dedicated circuit 103, and a light projector 105 to be described below;
the man-machine operation interface 102: an optional items provided according to the requirements of the applied installations, including switch, press button, keyboard, display, or one or multiple conventional operation interface in the form of video, audio, optical or RF to operate the dedicate circuit 103 and the light projector 105 that generates visible light;
the dedicated circuit 103: comprised of solid state electronic device, or dynamo-electric device, or integrated circuit and related software to provide functioning operation of the cabled control/transmission device adapted with a directional light projector;
a transmission conducting cable 104: comprised of a conducting cable that is directly connected to the main unit 110 or through a plug and socket set and may be provided as follows as applicable:
(1) An optical fiber to transmit optical signals and a conductor to transmit electric power are linked either directly or respectively by means of optical and electric linking devices connecting to the main unit 110 subject to be controlled or transmission by the optical fiber and the electric conductor; or
(2) An optical fiber to transmit optical signals is provided and directly linked to or linked by means of an optical linking device to the main unit 110 subject to be controlled or transmission by the optical fiber while the light projector 105 operates on its local DC source; or
(3) A transmission electric conducting cable for conduction is provided and directly linked to or linked by means of an electric linking device to the main unit 110 subject to be controlled or transmission by the conductor to transmit electric signals and power; and
the light projector 105: disposed to the casing of the control device and comprised of laser, diode, and associate drive circuit, or LED, bulb, or any other device to convert electric energy into visible light energy and associate drive circuit.

2. A cabled control/transmission device adapted with a directional light projector of claim 1, wherein the cabled control/transmission device adapted with a directional projector of the present invention is provided to control or transmit signals to the main unit 110 including that applied in information systems, communication systems, games, monitor systems, AV devices, computer, printer, recording devices, power toys, cabled control toys or any other home electric appliances, or any other electric appliance operating with =conducting cable as the control or transmission media for the cabled control/transmission device adapted with the directional light projector to control or transmit messages.

3. A cabled control/transmission device adapted with a directional light projector of claim 1, wherein the cabled control/transmission device adapted with the directional light projector of the present invention can be applied in hand held control device, mouse, trackball, keyboard, handset, MP3 player or any other control or transmission system that operates on a conducting cable as signal transmission media.

4. A cabled control/transmission device adapted with a directional light projector of claim 1, wherein the light projector 105 for generating visible light emits visible light-spot indication for the visible light spot to serve auxiliary assistance of presentation.

5. A cabled control/transmission device adapted with a directional light projector of claim 1, wherein the light projector 105 for generating visible light emits light projection beam for lighting purpose or for functioning as auxiliary assistance of presentation.

6. A cabled control/transmission device adapted with a directional light projector of claim 1, wherein the light projector 105 for generating visible light is further disposed with an optional optical lens and mechanism with range adjustable to select a focus as the light spot or to diffuse for lighting purpose.
